(19) United States
(12) Patent Application Publication
(10) Pub. No.: US 2026/0114167 A1
(43) Pub. Date: Apr. 23, 2026

(54) ANTI-REFLECTIVE FILM AND DISPLAY DEVICE INCLUDING THE SAME

(71) Applicant: SAMSUNG DISPLAY CO., LTD., YONGIN-SI (KR)

(72) Inventors: Hyeon Mi LEE, Yongin-si (KR); Da Hye KIM, Yongin-si (KR); Man Soo KIM, Yongin-si (KR); Jung Hyun KIM, Yongin-si (KR); Hyun Hyang KIM, Yongin-si (KR); Ju Young YOON, Yongin-si (KR)

(21) Appl. No.: 19/225,342

(22) Filed: Jun. 2, 2025

(30) Foreign Application Priority Data
Oct. 17, 2024 (KR) 10-2024-0141702

(51) Int. Cl. H10K 59/80

(52) U.S. Cl. CPC H10K 59/8791

(57) ABSTRACT

An anti-reflective film and a display device including the same is provided. The anti-reflective film includes a first refractive layer and a second refractive layer disposed on the first refractive layer. A refractive index of the first refractive layer is greater than a refractive index of the second refractive layer. The first refractive layer includes a first sub-layer and a second sub-layer disposed on the first sub-layer. A first nano-composite layer is formed between the first sub-layer and the second sub-layer. The first nano-composite layer includes a material formed by bonding a material of the first sub-layer with a material of the second sub-layer. A thickness of the first sub-layer is at least 1.2 times larger than a thickness of the second sub-layer. The thickness of the second sub-layer is less than 5 nm.

### CROSS-REFERENCE TO RELATED APPLICATION

This application claims priority under 35 U.S.C. § 119 to Korean Patent Application No. 10-2024-0141702 filed on Oct. 17, 2024 in the Korean Intellectual Property Office, the contents of which are herein incorporated by reference in its entirety.

### TECHNICAL FIELD

The present disclosure relates to a display device and, more specifically, to an anti-reflective film and a display device including the same.

### DISCUSSION OF THE RELATED ART

As the digital age progresses, the demand for display devices continues to grow across various applications. These devices are now widely used in electronic products such as smartphones, digital cameras, laptop computers, navigation systems, and smart televisions.

When a display device is exposed to external light sources, including natural sunlight or artificial lighting, the reflected light can reduce image clarity and contribute to user eye strain. To address this issue, there is a growing demand for display technologies with anti-reflective properties.

### SUMMARY

An anti-reflective film includes a first refractive layer and a second refractive layer disposed on the first refractive layer. A refractive index of the first refractive layer is greater than a refractive index of the second refractive layer. The first refractive layer includes a first sub-layer and a second sub-layer disposed on the first sub-layer. A first nano-composite layer is formed between the first sub-layer and the second sub-layer. The first nano-composite layer includes a material formed by bonding a material of the first sub-layer with a material of the second sub-layer. A thickness of the first sub-layer is at least 1.2 times larger than a thickness of the second sub-layer. The thickness of the second sub-layer is less than 5 nm.

The first refractive layer further may include a third sub-layer disposed on the second sub-layer and a fourth sub-layer disposed on the third sub-layer. A second nano-composite layer may be formed between the third sub-layer and the fourth sub-layer. The second nano-composite layer may include a material formed by bonding a material of the third sub-layer with a material of the fourth sub-layer. A thickness of the third sub-layer may be at least 1.2 times larger than a thickness of the fourth sub-layer. The thickness of the fourth sub-layer may be less than 5 nm.

The first sub-layer, the second sub-layer, the third sub-layer, and the fourth sub-layer each independently may include at least one of silicon nitride, a metal nitride, and a semi-metal nitride.

The metal nitride may include at least one of AlN, ZrN, TiN, CrN, Mn₄N, FeNₓ, CoNₓ, Ni₃N, Cu₃N, Zn₂N₃, VN, Mo₂N, and HfN.

The semi-metal nitride may include Ge₃N₄ or Pb(N₃)₂.

The first sub-layer and the second sub-layer respectively may include AlN or SiNₓ. The first nano-composite layer may include AlSiN. A thickness of the first sub-layer may be at least 10 times larger than a thickness of the second sub-layer. The thickness of the second sub-layer may be less than 2 nm.

When the first sub-layer includes AlN and the second sub-layer includes ZrN or TiN, the first nano-composite layer may include AlZrN or AlTiN. A thickness of the first sub-layer may be at least 1.4 times larger than a thickness of the second sub-layer. The thickness of the second sub-layer may be less than 4 nm.

When the first sub-layer may include CrN and the second sub-layer includes AlN, the first nano-composite layer may include CrAlN. A thickness of the first sub-layer may at least 2 times larger than a thickness of the second sub-layer. The thickness of the second sub-layer may less than 3 nm.

The anti-reflective film may further include a third refractive layer disposed on the second refractive layer. A fourth refractive layer may be disposed on the third refractive layer. A refractive index of the third refractive layer may be greater than a refractive index of the fourth refractive layer.

The third refractive layer may include a fifth sub-layer. A sixth sub-layer may be disposed on the fifth sub-layer. A third nano-composite layer may be formed between the fifth sub-layer and the sixth sub-layer. The third nano-composite layer may include a material formed by bonding the material of the fifth sub-layer with the material of the sixth sub-layer. A thickness of the fifth sub-layer may be at least 1.2 times larger than a thickness of the sixth sub-layer. The thickness of the sixth sub-layer may be less than 5 nm.

The anti-reflective film may have a hardness of at least 20 GPa at a thickness of 50 nm to 600 nm.

The anti-reflective film may have a hardness of at least 22 GPa at a thickness of 600 nm to 800 nm.

The anti-reflective film may have a hardness of at least 24 GPa at a thickness of 800 nm to 1,000 nm.

An anti-reflective film includes a first refractive layer and a second refractive layer disposed on the first refractive layer. A refractive index of the first refractive layer is greater than a refractive index of the second refractive layer. The first refractive layer includes a first sub-layer. A second sub-layer is disposed on one surface of the first sub-layer. A third sub-layer is disposed on the second sub-layer. A first nano-composite layer is formed between the first sub-layer and the second sub-layer. The first nano-composite layer includes a material formed by bonding a material of the first sub-layer with a material of the second sub-layer. A thickness of the first sub-layer is at least 1.2 times larger than a thickness of the second sub-layer. The thickness of the second sub-layer is less than 5 nm.

The third sub-layer may include at least one of silicon nitride (Si₃N₄), aluminum nitride (AlN), zirconium nitride (ZrN), chromium nitride (CrN), titanium nitride (TiN), manganese nitride (Mn₄N), iron nitride (FeNₓ), cobalt nitride (CoNₓ), nickel nitride (Ni₃N), copper nitride (Cu₃N), zinc nitride (Zn₂N₃), vanadium nitride (VN), molybdenum nitride (Mo₂N), hafnium nitride (HfN), germanium nitride (Ge₃N₄), lead nitride (Pb(N₃)₂), titanium niobium oxide (Ti₄Nb₃O₃₅), titanium dioxide (TiO₂), zirconium dioxide (ZrO₂), lithium niobate (LiNbO₃), lithium tantalate (LiTaO₃), and lanthanum titanium oxide (LaTiO₂).

The first refractive layer further may include a third sub-layer disposed on the second sub-layer. A fourth sub-layer may be disposed on the third sub-layer. A second nano-composite layer may be formed between the third sub-layer and the fourth sub-layer. The second nano-composite layer may include a material formed by bonding a material of the third sub-layer with a material of the fourth sub-layer. A thickness of the third sub-layer may be at least 1.2 times larger than a thickness of the fourth sub-layer. The thickness of the fourth sub-layer may be less than 5 nm.

The first refractive layer further may include a fourth sub-layer disposed on the other surface of the first sub-layer.

A display device includes a display panel. An anti-reflective film is disposed on the display panel. A window is disposed on the anti-reflective film. The anti-reflective film includes a first refractive layer and a second refractive layer disposed on the first refractive layer. A refractive index of the first refractive layer is greater than a refractive index of the second refractive layer. The first refractive layer includes a first sub-layer and a second sub-layer disposed on one surface of the first sub-layer. A first nano-composite layer is formed between the first sub-layer and the second sub-layer. The first nano-composite layer includes a material formed by bonding a material of the first sub-layer with a material of the second sub-layer. A thickness of the first sub-layer may be at least 1.2 times larger than a thickness of the second sub-layer. The thickness of the second sub-layer may be less than 5 nm.

The first refractive layer may further include a third sub-layer disposed on the second sub-layer.

The first refractive layer may further include a fourth sub-layer disposed on the other surface of the first sub-layer.

An electronic device includes a display device configured to display an image and a processor configured to transmit an image data signal to the display device. The display device includes a display panel. An anti-reflective film is disposed on the display panel. A window is disposed on the anti-reflective film. The anti-reflective film includes a first refractive layer and a second refractive layer disposed on the first refractive layer. A refractive index of the first refractive layer is greater than a refractive index of the second refractive layer. The first refractive layer includes a first sub-layer and a second sub-layer disposed on one surface of the first sub-layer. A first nano-composite layer is formed between the first sub-layer and the second sub-layer, The first nano-composite layer includes a material formed by bonding a material of the first sub-layer with a material of the second sub-layer. A thickness of the first sub-layer is at least 1.2 times larger than a thickness of the second sub-layer. The thickness of the second sub-layer is less than 5 nm.

The first refractive layer may further include a third sub-layer disposed on the second sub-layer and a fourth sub-layer disposed on the third sub-layer. A second nano-composite layer may be formed between the third sub-layer and the fourth sub-layer. The second nano-composite layer may include a material formed by bonding a material of the third sub-layer with a material of the fourth sub-layer. A thickness of the third sub-layer may be at least 1.2 times larger than a thickness of the fourth sub-layer. The thickness of the fourth sub-layer may be less than 5 nm.

The first sub-layer, the second sub-layer, the third sub-layer, and the fourth sub-layer each independently include at least one of silicon nitride, a metal nitride, and a semi-metal nitride.

The metal nitride may include at least one of AlN, ZrN, TiN, CrN, Mn₄N, FeNₓ, CoNₓ, Ni₃N, Cu₃N, Zn₂N₃, VN, Mo₂N, and HfN. The semi-metal nitride may include Ge₃N₄ or Pb(N₃)₂.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a display device according to an embodiment of the present disclosure;

FIG. 2 is an exploded perspective view of the display device according to an embodiment of the present disclosure;

FIG. 3 is a side view of the display device according to an embodiment of the present disclosure;

FIG. 4 is a schematic cross-sectional view of a display panel according to an embodiment of the present disclosure;

FIG. 5 is a diagram illustrating an example of an anti-reflective film in the display device according to an embodiment of the present disclosure;

FIG. 6 is a cross-sectional view illustrating an example of a refractive layer of the anti-reflective film in the display device according to an embodiment of the present disclosure;

FIG. 7 is a cross-sectional view illustrating an example of the refractive layer of the anti-reflective film in the display device according to an embodiment of the present disclosure;

FIG. 8 is a graph showing the hardness and elasticity according to the silicon (Si) content of AlSiN according to an embodiment of the present disclosure;

FIG. 9 is a cross-sectional view illustrating an example of the refractive layer of the anti-reflective film in the display device according to an embodiment of the present disclosure;

FIG. 10 is a cross-sectional view illustrating an example of the refractive layer of the anti-reflective film in the display device according to an embodiment of the present disclosure;

FIG. 11 is a cross-sectional view illustrating an example of the refractive layer of the anti-reflective film in the display device according to an embodiment of the present disclosure;

FIG. 12 is a diagram illustrating an example of the anti-reflective film in the display device according to an embodiment of the present disclosure;

FIG. 13 is a cross-sectional view illustrating an example of the refractive layer of the anti-reflective film in the display device according to an embodiment of the present disclosure;

FIG. 14 is a cross-sectional view illustrating an example of the refractive layer of the anti-reflective film in the display device according to an embodiment of the present disclosure;

FIG. 15 is a cross-sectional view illustrating an example of the refractive layer of the anti-reflective film in the display device according to an embodiment of the present disclosure;

FIG. 16 is a cross-sectional view illustrating an example of the refractive layer of the anti-reflective film in the display device according to an embodiment of the present disclosure;

FIG. 17 is a cross-sectional view illustrating an example of the refractive layer of the anti-reflective film in the display device according to an embodiment of the present disclosure;

FIG. 18 is a High Resolution-Transmission Electron Microscopy (HR-TEM) image showing the thickness of a second sub-layer of the refractive layer in the display device according to an embodiment of the present disclosure; and

FIG. 19 is a graph showing the hardness according to the thickness of the second sub-layer of the refractive layer in the display device according to an embodiment of the present disclosure.

### DETAILED DESCRIPTION

The aspects and features of the present invention, and the methods for achieving them, will become clear with reference to the embodiments described in detail below with the accompanying drawings. However, the present invention is not necessarily limited to the embodiments disclosed below, but may be implemented in various different forms, and these embodiments are provided to make the disclosure of the present invention complete and to fully inform those skilled in the art of the invention of the scope of the invention.

When elements or layers are referred to as “on” another element or layer, this includes all cases where another layer or another element is interposed directly on or in the middle of the other element. The same reference numerals may refer to the same components throughout the specification and the drawings. The shapes, sizes, ratios, angles, numbers, or the like disclosed in the drawings for explaining the embodiments are offered as examples, and therefore the present invention is not necessarily limited to the examples illustrated.

Each feature of the various embodiments of the present invention may be partially or wholly combined or combined with each other, and may be technically capable of various interconnections and operations. Each embodiment may be implemented independently of each other, or may be implemented together in a related relationship. Specific embodiments are described below with reference to the attached drawings.

Embodiments of the present disclosure relate to an anti-reflective film that may be used as part of a display device for reducing an amount of reflection or glare that might otherwise reduce the display quality of the display device while also serving as a protective layer that protects the display device from impact and other potentially damaging contact. The anti-reflective film is structured with multiple refractive layers, each having different refractive indices to reduce reflections and improve visibility under external light sources. A key innovation in the design is the use of nano-composite layers that bond materials between sub-layers, increasing hardness and structural integrity without significantly increasing thickness. This anti-reflection film may be integrated into display devices, such as OLED screens, to improve viewing experiences by minimizing glare and eye strain while maintaining durability.

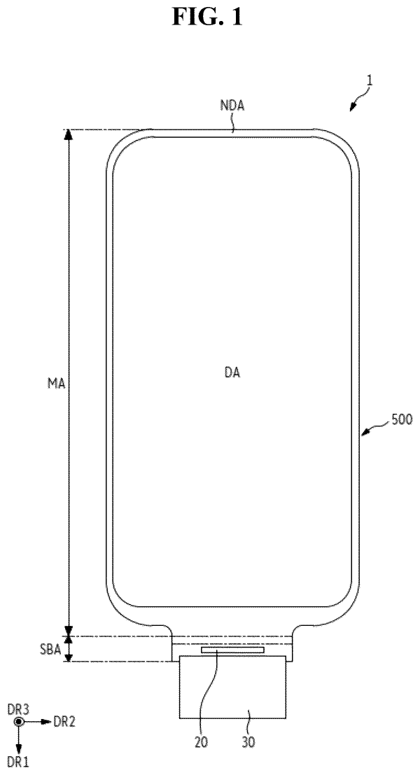

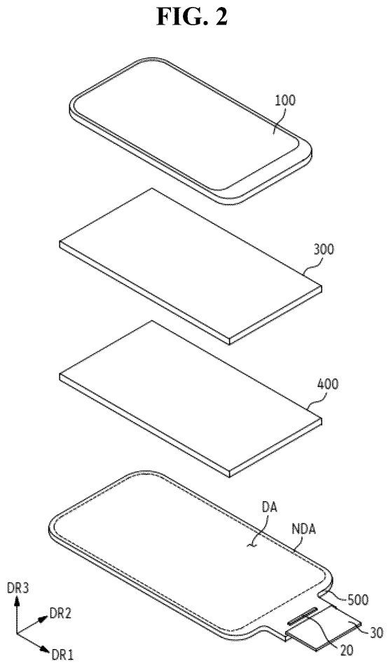

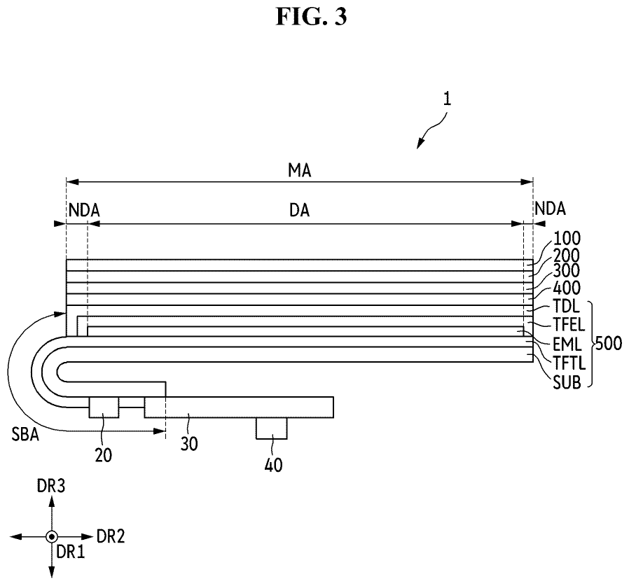

FIG. 1 is a plan view of a display device according to an embodiment of the present disclosure. FIG. 2 is an exploded perspective view of the display device according to an embodiment of the present disclosure. FIG. 3 is a side view of the display device according to an embodiment of the present disclosure.

Referring to FIGS. 1 through 3, a display device 1 may include a window 100, an adhesive 200, a fingerprint-resistant film 300, an anti-reflective film 400, and a display panel 500.

The display device 1 is a device that displays moving or still images and may be used as a display screen for various products, including portable electronic devices such as mobile phones, smartphones, tablet PCs, smartwatches, watch phones, mobile communication terminals, electronic notebooks, e-book readers, portable multimedia players, navigation systems, Ultra Mobile PCs (UMPCs), as well as televisions, laptops, computer monitors, advertising displays, and Internet of Things (IoT) devices.

The display device 1 may be a light-emitting display device, such as an organic light-emitting display device using organic light-emitting diodes (OLEDs), a quantum dot light-emitting display device containing a quantum dot emission layer, an inorganic light-emitting display device containing inorganic semiconductors, or a micro- or nano-light-emitting display device using micro- or nano-light-emitting diodes (LEDs). The display device 1 will hereinafter be described as being an organic light-emitting display device, but the present disclosure is not necessarily limited thereto.

The display device 1 includes a display panel 500, a display driving circuit 20, and a circuit board 30.

The display panel 100 may be formed as a rectangular plane with a pair of short sides extending in a first direction DR1 and a pair of long sides extending in a second direction DR2 intersecting the first direction DR1. The display panel 100 may also have a thickness in a third direction DR3 intersecting both the first and second directions DR1 and DR2. The corners where the short sides in the first direction DR1 and the long sides in the second direction DR2 meet may be rounded with a selected curvature or may be formed at a right angle. The planar shape of the display panel 100 is not necessarily limited to a rectangle and may be formed as another polygon, a circle, or an ellipse. The display panel 100 may be formed flat but is not necessarily limited thereto. For example, the display panel 100 may include curved sections formed at the left and right ends with a constant or varying curvature. Additionally, the display panel 100 may be flexibly formed to be bendable, curvable, foldable, or rollable to a noticeable extent without cracking or otherwise sustaining damage.

The display panel 100 may include a main area MA and a sub-area SBA.

The main area MA may include a display area DA for displaying images and a non-display area NDA surrounding the display area DA. The display area DA may occupy most of the main area MA. The display area DA may be disposed at the center of the main area MA. The non-display area NDA may be disposed adjacent to the display area DA. The non-display area NDA may be the outer area of the display area DA. The non-display area NDA may surround the display area DA. The non-display area NDA may be the edge area of the display panel 100.

The sub-area SBA may extend in the first direction DR1 from one side of the main area MA. The length of the sub-area SBA in the first direction DR1 may be smaller than the length of the main area MA in the first direction DR1. The length of the sub-area SBA in the second direction DR2 may be smaller than or substantially equal to the length of the main area MA in the second direction DR2. The sub-area SBA may be bent and disposed below the display panel 100. In this case, the sub-area SBA may overlap with the main area MA in the third direction DR3.

The display driving circuit 20 may generate signals and voltages for driving the display panel 100. The display driving circuit 20 may be formed as an integrated circuit (IC) and attached to the sub-area SBA of the display panel 100 by a chip-on-glass (COG) method, a chip-on-plastic (COP) method, or an ultrasonic bonding method. Alternatively, the display driving circuit 20 may be attached to the circuit board 30 by a chip-on-film (COF) method.

The circuit board 30 may be attached to one end of the sub-area SBA of the display panel 100. As a result, the circuit board 30 may be electrically connected to the display panel 100 and the display driving circuit 20. The display panel 100 and the display driving circuit 20 may receive digital video data, timing signals, and drive voltages via the circuit board 30. The circuit board 30 may be a flexible printed circuit board (FPCB), a printed circuit board (PCB), or a flexible film such as a COF.

The window 100 may be attached to the front surface of the fingerprint-resistant film 300 by the adhesive 200. The window 100 may include a transparent material, such as glass or plastic. For example, the window 100 may be ultra-thin glass (UTG) with a thickness of 0.1 mm or less or a transparent polyimide (PI) film.

The adhesive 200 may be a transparent adhesive film or a transparent adhesive resin. For example, the adhesive 200 may include a transparent adhesive such as a pressure-sensitive adhesive (PSA) or an optically clear adhesive (OCA). The first adhesive 300 may include an acrylic-based adhesive material.

The fingerprint-resistant film 300 may be disposed on the front surface of the window 100. The fingerprint-resistant film 300 may prevent the fingerprints of a user from adhering to the display device 1.

The anti-reflective film 400 may be disposed on the front surface of the display panel 500. The anti-reflective film 400 may include a plurality of refractive layers with different refractive indices. The anti-reflective film 400 can reduce reflected light through the refractive layers. The anti-reflective film 400 will be described later in detail.

The display device 1 may further include, below the display panel 500, a light-shielding layer to absorb ambient light, a buffer layer to absorb external impacts, and a heat-dissipating layer for efficient heat dissipation of the display panel 500.

The light-shielding layer may block light transmission to prevent the components disposed below the light-shielding layer from being visible from the top of the display panel 500. The light-shielding layer may include a light-absorbing material such as black pigment or black dye.

The buffer layer may help to absorb/dissipate external impact to prevent damage to the display panel 500. The buffer layer may be formed as a single layer or as a multi-layered structure. For example, the buffer layer may include a polymer resin such as polyurethane, polycarbonate, polypropylene, or polyethylene, or may include an elastic material such as foam-molded sponge formed from rubber, a urethane-based material, or an acrylic-based material.

The heat-dissipating layer may include a first heat-dissipating layer containing a material such as graphite or carbon nanotubes, and a second heat-dissipating layer formed as a thin metal film with excellent thermal conductivity and electromagnetic wave shielding properties, include a metal such as copper, nickel, iron, or silver.

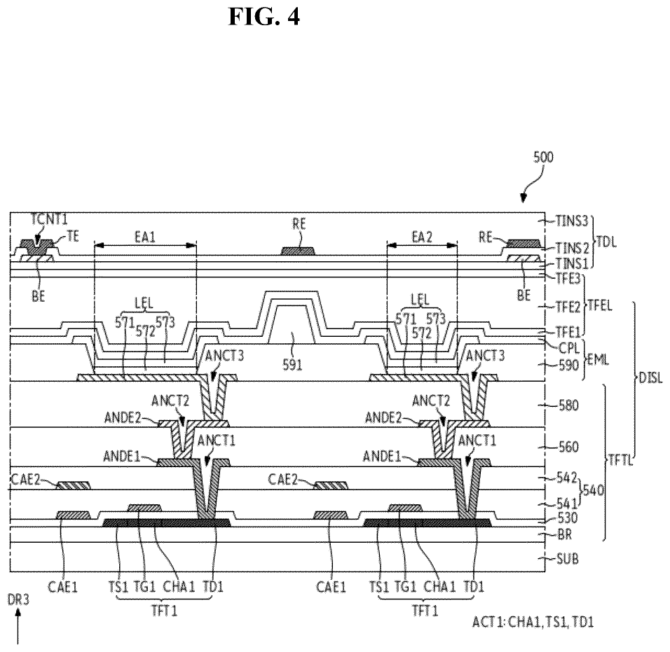

FIG. 4 is a schematic cross-sectional view of a display panel according to an embodiment of the present disclosure.

Referring to FIG. 4, a display panel 500 may include a substrate SUB, a display layer DISL disposed on the substrate SUB, and a touch detection layer TDL disposed on the display layer DISL. The display layer DISL may include a thin film transistor layer TFTL, a light-emitting element layer EML, and an encapsulation layer TFEL.

A thin film transistor layer TFTL may be disposed on the substrate SUB. The thin film transistor layer TFTL may include a barrier film BR, thin film transistors TFT1, first capacitor electrodes CAEL, second capacitor electrodes CAE2, first anode connection electrodes ANDE1, second anode connection electrodes ANDE2, a gate insulating film 530, a first interlayer insulating film 541, a second interlayer insulating film 542, a first planarization film 560, and a second planarization film 580.

The substrate SUB may include an insulating material such as a polymer resin. For example, the substrate SUB may include polyimide. The substrate SUB may be a flexible substrate capable of bending, folding, or rolling to a noticeable extent without cracking or otherwise sustaining damage.

The barrier film BR may be disposed on the substrate SUB. The barrier film BR protects the thin film transistors TFT1 in the thin film transistor layer TFTL and emission layers 572 of the light-emitting element layer EML from moisture that may penetrate through the moisture-sensitive substrate SUB. The barrier film BR may include a plurality of inorganic films that are alternately stacked. For example, the barrier film BR may be in a multi-layer structure with one or more inorganic films selected from a silicon nitride layer, a silicon oxynitride layer, a silicon oxide layer, a titanium oxide layer, and an aluminum oxide layer.

The thin film transistors TFT1 may be disposed on the barrier film BR. An active layer ACT1 of the thin film transistors TFT1 may be disposed on the barrier film BR. The active layer ACT1 may include polycrystalline silicon, monocrystalline silicon, low-temperature polycrystalline silicon, amorphous silicon, or an oxide semiconductor.

The active layer ACT1 may include channel regions CHA1, source regions TS1, and drain regions TD1. The channel regions CHA1 may overlap with gate electrodes TG1 in the thickness direction of the substrate SUB, i.e., in the third direction DR3. The source regions TS1 may be disposed on first sides of the channel regions CHA1, and the drain regions TD1 may be disposed on second sides of the channel regions CHA1. The source regions TS1 and the drain regions TD1 may be regions that do not overlap with the gate electrodes TG1 in the third direction DR3. The source regions TS1 and the drain regions TD1 may be regions with increased conductivity, formed by doping a silicon semiconductor or an oxide semiconductor with ions or impurities.

A gate insulating film 530 may be disposed on the active layer ACT1. The gate insulating film 530 may be an inorganic film, such as a silicon nitride layer, a silicon oxynitride layer, a silicon oxide layer, a titanium oxide layer, or an aluminum oxide layer.

The gate electrodes TG1 of the thin film transistors TFT1 and the first capacitor electrodes CAE1 may be disposed on the gate insulating film 530. The gate electrodes TG1 may overlap with the channel regions CHA1 in the third direction DR3. In FIG. 4, the gate electrodes TG1 and the first capacitor electrodes CAE1 are illustrated as being separated, but may be connected and formed integrally as a single continuous and undifferentiated structure. The gate electrodes TG1 and the first capacitor electrodes CAE1 may be formed as single or multi-layer structures containing one of molybdenum (Mo), aluminum (Al), chromium (Cr), gold (Au), titanium (Ti), nickel (Ni), neodymium (Nd), copper (Cu), or an alloy thereof.

A first interlayer insulating film 541 may be disposed on the gate electrodes TG1 and the first capacitor electrodes CAEL1 of the thin film transistors TFT1. The first interlayer insulating film 541 may be an inorganic film, such as a silicon nitride layer, a silicon oxynitride layer, a silicon oxide layer, a titanium oxide layer, or an aluminum oxide layer. The first interlayer insulating film 541 may include a plurality of inorganic films.

The second capacitor electrodes CAE2 may be disposed on the first interlayer insulating film 541. The second capacitor electrodes CAE2 may overlap with the first capacitor electrodes CAEL1 of the thin film transistors TFT1 in the third direction DR3. Additionally, when the gate electrodes TG1 and the first capacitor electrodes CAEL1 are formed integrally, the second capacitor electrodes CAE2 may overlap with the gate electrodes TG1 in the third direction DR3. Because the first interlayer insulating film 541 has a selected dielectric constant, capacitors may be formed by the first capacitor electrodes CAEL1, the second capacitor electrodes CAE2, and the first interlayer insulating film 541 disposed between the first capacitor electrodes CAE1 and the second capacitor electrodes CAE2. The second capacitor electrodes CAE2 may be single or multi-layer structures of one of Mo, Al, Cr, Au, Ti, Ni, Nd, Cu, or an alloy thereof.

The second interlayer insulating film 542 may be disposed on the second capacitor electrodes CAE2. The second interlayer insulating film 542 may be an inorganic film, such as a silicon nitride layer, a silicon oxynitride layer, a silicon oxide layer, a titanium oxide layer, or an aluminum oxide layer. The second interlayer insulating film 542 may include a plurality of inorganic films.

The first anode connection electrodes ANDE1 may be disposed on the second interlayer insulating film 542. The first anode connection electrodes ANDE1 may be connected to the drain regions TD1 of the thin film transistors TFT1 through first connection contact holes ANCT1, which pass through the gate insulating film 530, the first interlayer insulating film 541, and the second interlayer insulating film 542. The first anode connection electrodes ANDE1 may be single or multi-layer structures of one of Mo, Al, Cr, Au, Ti, Ni, Nd, Cu, or an alloy thereof.

The first planarization film 560 may be disposed on the first anode connection electrodes ANDE1 to planarize the step caused by the thin film transistors TFT1. The first planarization film 560 may be formed as an organic film from a material such as an acrylic resin, epoxy resin, phenolic resin, polyamide resin, or polyimide resin.

The second anode connection electrodes ANDE2 may be disposed on the first planarization film 560. The second anode connection electrodes ANDE2 may be connected to the first anode connection electrodes ANDE1 through second connection contact holes ANCT2 that penetrate the first planarization film 560. The second anode connection electrodes ANDE2 may be formed as single-layer or multi-layer structures of one of Mo, Al, Cr, Au, Ti, Ni, Nd, Cu, or an alloy thereof.

The second planarization film 580 may be disposed on the second anode connection electrodes ANDE2. The second planarization film 580 may be formed as an organic film from a material such as an acrylic resin, epoxy resin, phenolic resin, polyamide resin, or polyimide resin.

The light-emitting element layer EML, including light-emitting elements LEL and a bank 590, may be disposed on the second planarization film 580. The light-emitting elements LEL may respectively include a pixel electrode 571, an emission layer 572, and a common electrode 573.

The pixel electrodes 571 may be disposed on the second planarization film 580. The pixel electrodes 571 may be connected to the second anode connection electrodes ANDE2 through third connection contact holes ANCT3 that penetrate the second planarization film 580.

In a top emission structure, where light is emitted toward the common electrodes 573 with respect to the emission layers 572, the pixel electrodes 571 may include a high-reflectance metal material such as a laminated structure of titanium/aluminum/titanium (Ti/Al/Ti), indium tin oxide/aluminum/indium tin oxide (ITO/Al/ITO), indium tin oxide/silver/indium tin oxide (ITO/Ag/ITO), a silver-palladium-copper (APC) alloy, or a laminated structure of an APC alloy and indium tin oxide (ITO/APC/ITO).

The bank 590 may be formed on the second planarization film 580 to partition the pixel electrode 571, thereby defining emission parts (EA1 and EA2). The bank 590 may be disposed to cover the edges of the pixel electrode 571. The bank 590 may be formed as an organic film from a material such as an acrylic resin, epoxy resin, phenolic resin, polyamide resin, or polyimide resin.

First emission parts EA1 and second emission parts EA2 may include the pixel electrodes 571, the emission layers 572, and the common electrodes 573 that are sequentially stacked, and represent regions where holes from the pixel electrodes 571 and electrons from the common electrodes 573 recombine in the emission layers 572 to emit light.

The emission layers 572 may be disposed on the pixel electrodes 571 and the bank 590. The emission layers 572 may include an organic material that emits a selected color of light. For example, the emission layers 572 may include hole transport layers, organic material layers, and electron transport layers.

The common electrodes 573 may be disposed on the emission layers 572. The common electrodes 573 may cover the emission layers 572. The common electrodes 573 may be common layers formed over both the first emission parts EA1 and the second emission parts EA2.

In the top emission structure, the common electrodes 573 may be formed from a transparent conductive oxide (TCO), such as indium tin oxide (ITO) or indium zinc oxide (IZO), or a semi-transmissive conductive material, such as Mg, Ag, or an alloy of Mg and Ag. When the common electrodes 573 are formed from a semi-transmissive conductive material, light extraction efficiency may be enhanced by a micro-cavity effect.

A spacer 591 may be disposed on the bank 590. The spacer 591 may support a mask during the manufacture of the emission layers 572. The spacer 591 may be formed as an organic film from a material such as an acrylic resin, epoxy resin, phenolic resin, polyamide resin, or polyimide resin.

In some embodiments, the display panel 500 may further include a capping layer CPL disposed on the common electrodes 573. The capping layer CPL may include an inorganic material. For example, the capping layer CPL may include at least one material selected from silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

An encapsulation layer TFEL may be disposed on the common electrodes 573. The encapsulation layer TFEL may include at least one inorganic film to prevent oxygen or moisture from penetrating the light-emitting element layers EML. Additionally, the encapsulation layer TFEL may include at least one organic film to protect the light-emitting element layers EML from contaminants such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be disposed on the common electrodes 573, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be multi-layer structures formed by alternately stacking one or more inorganic films selected from silicon nitride, silicon oxynitride, silicon oxide, titanium oxide, and aluminum oxide layers. The encapsulation organic film TFE2 may be an organic film, such as an acrylic resin, epoxy resin, phenolic resin, polyamide resin, or polyimide resin.

The touch detection layer TDL may be disposed on the encapsulation layer TFEL. The touch detection layer TDL may include a first touch insulating film TINS1, connection electrodes BE, a second touch insulating film TINS2, driving electrodes TE, sensing electrodes RE, and a third touch insulating film TINS3.

The first touch insulating film TINS1 may be disposed on the encapsulation layer TFEL. The first touch insulating film TINS1 may be an inorganic film, such as a silicon nitride layer, a silicon oxynitride layer, a silicon oxide layer, a titanium oxide layer, or an aluminum oxide layer.

The connection electrodes BE may be disposed on the first touch insulating film TINS1. The connection electrodes BE may be formed as single-layer or multi-layer structures of one of Mo, Al, Cr, Au, Ti, Ni, Nd, Cu, and/or an alloy thereof.

The second touch insulating film TINS2 may be disposed on the connection electrodes BE. The second touch insulating film TINS2 may be an inorganic film, such as a silicon nitride layer, a silicon oxynitride layer, a silicon oxide layer, a titanium oxide layer, or an aluminum oxide layer. Alternatively, the second touch insulating film TINS2 may be formed as an organic film from a material such as an acrylic resin, epoxy resin, phenolic resin, polyamide resin, or polyimide resin.

The driving electrodes TE and the sensing electrodes RE may be disposed on the second touch insulating film TINS2. The driving electrodes TE and the sensing electrodes RE may be formed as single-layer or multi-layer structures of one of Mo, Al, Cr, Au, Ti, Ti, Ni, Nd, Cu, and/or an alloy thereof.

The driving electrodes TE and the sensing electrodes RE may overlap with the connection electrodes BE in the third direction DR3. The driving electrodes TE may be connected to the connection electrodes BE through touch contact holes TCNT1 that pass through the first touch insulating film TINS1.

The third touch insulating film TINS3 may be formed on the driving electrodes TE and the sensing electrodes RE. The third touch insulating film TINS3 may planarize the step created by the driving electrodes TE, the sensing electrodes RE, and the connection electrodes BE. The third touch insulating film TINS3 may be formed as an organic film using a material such as an acrylic resin, epoxy resin, phenolic resin, polyamide resin, or polyimide resin.

Various embodiments of the anti-reflective film 400 will hereinafter be described.

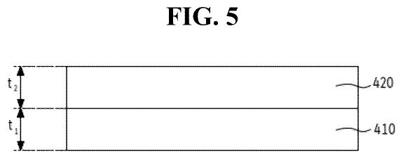

FIG. 5 is a diagram illustrating an example of the anti-reflective film in the display device according to an embodiment of the present disclosure.

Referring to FIG. 5, the anti-reflective film 400 may include a first refractive layer 410 and a second refractive layer 420.

The refractive index of the first refractive layer 410 may be greater than the refractive index of the second refractive layer 420. The refractive index of the first refractive layer 410 may range from 1.70 to 2.80, but is not necessarily limited thereto. The refractive index of the second refractive layer 420 may range from 1.20 to 1.50, but is not necessarily limited thereto. The first refractive layer 410 may correspond to a relatively high-refractive-index layer, and the second refractive layer 420 may correspond to a relatively low-refractive-index layer.

The second refractive layer 420 may include at least one of silicone resin, silica, and silicon dioxide (SiO₂) but is not necessarily limited thereto. The second refractive layer 420 may also include any other material suitable for achieving a low refractive index.

A thickness t₁ of the first refractive layer 410 and a thickness t₂ of the second refractive layer 420 may be the same or different from one another. The thicknesses t₁ and t₂ of the first and second refractive layers 410 and 420 may be determined based on characteristics such as the target reflection wavelength, hardness, durability, and reflectance of the anti-reflective film 400.

The thicknesses t₁ and t₂ of the first and second refractive layers 410 and 420 may be calculated according to Equation 1.

$$t = \frac{λ}{4 n} \qquad [ Equation 1 ]$$

In Equation 1, “t” denotes the thickness t₁ or t₂ of the first or second refractive layer 410 or 420 in the anti-reflective film 400, “λ” denotes the target reflection wavelength of the anti-reflective film 400, and “n” denotes the refractive index of the first or second refractive layer 410 or 420.

For example, if the target reflection wavelength of the anti-reflective film 400 is 500 nm and the refractive index of the first refractive layer 410 is 2.3, the thickness t may be approximately 54 nm. Alternatively, if the target reflection wavelength of the anti-reflective film 400 is 500 nm and the refractive index of the second refractive layer 420 is 1.2, the thickness t may be approximately 104 nm.

Generally, a high-refractive-index layer has a greater hardness than a low-refractive-index layer, and to enhance the durability of the anti-reflective film 400, the hardness of the high-refractive-index layer may be increased.

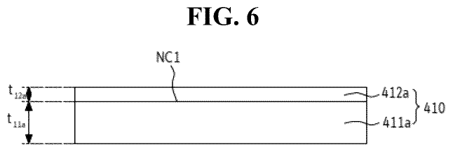

FIG. 6 is a cross-sectional view illustrating an example of a refractive layer of the anti-reflective film in the display device according to an embodiment of the present disclosure.

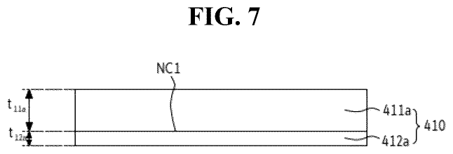

FIG. 7 is a cross-sectional view illustrating an example of the refractive layer of the anti-reflective film in the display device according to an embodiment of the present disclosure.

Referring to FIGS. 6 and 7, the first refractive layer 410 may include a first sub-layer 411a, a second sub-layer 412a, and a first nano-composite layer NC.

As illustrated in FIG. 6, the second sub-layer 412a may be disposed on the first sub-layer 411a of the first refractive layer 410. Alternatively, as illustrated in FIG. 7, the first sub-layer 411a may be disposed on the second sub-layer 412a of the first refractive layer 410.

The first nano-composite layer NC1 may be formed between the first and second sub-layers 411a and 412a. The first nano-composite layer NC1 may be formed by the bonding of the materials of the first and second sub-layers 411a and 412a. The materials of the first and second sub-layers 411a and 412a may have similar structures to each other.

For example, when the first sub-layer 411a is AlN and the second sub-layer 412a is Si₃N₄, the first nano-composite layer NC1 may be AlSiN. To form the first sub-layer 411a, AlN may be deposited using an Al target in a nitrogen atmosphere, and then to form the second sub-layer 412a on the first sub-layer 411a, Si₃N₄ may be deposited using an Si target in a nitrogen atmosphere. Due to the structural similarity between AlN and Si₃N₄ at the interface of the first and second sub-layers 411a and 412a, a first nano-composite layer NC1 of AlSiN with excellent hardness may be formed as a product of crystal growth. The AlSiN in the first nano-composite layer NC1 exhibits superior hardness characteristics compared to AlN, Si₃N₄, or AlSiN deposited as a single layer.

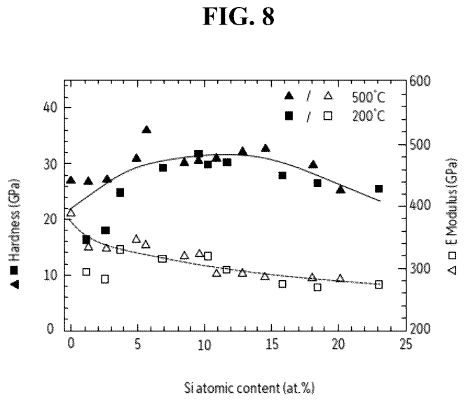

FIG. 8 is a graph showing the hardness and elasticity of AlSiN according to the Si content according to an embodiment of the present disclosure.

Referring to FIG. 8, the hardness characteristics of AlSiN vary depending on the Si content, with the hardness of AlSiN being the highest when the Si content is approximately 10%. However, when forming AlSiN, it is challenging to precisely implement the Si content by finely controlling the contents of Al, Si, and nitrogen, making it difficult to form AlSiN with consistent hardness.

In contrast, AlN of the first sub-layer 411a and Si₃N₄ of the second sub-layer 412a may form a stable crystal structure at their interface through bonding due to structural similarity.

As a high-hardness first nano-composite layer NC1 is formed between the first and second sub-layers 411a and 412a, the hardness of the first refractive layer 410 may be increased.

A thickness t₁₂ₐ of the second sub-layer 412a may be less than 5 nm, and a thickness t₁₁ₐ of the first sub-layer 411a may be at least 1.2 times the thickness t₁₂ₐ of the second sub-layer 412a. The thicknesses t₁₁ₐ and t₁₂ₐ of the first and second sub-layers 411a and 412a may vary depending on the materials of the first and second sub-layers 411a and 412a.

By adjusting the thicknesses t₁₁ₐ and t₁₂ₐ of the first and second sub-layers 411a and 412a, the first nano-composite layer NC1 may be formed. When the thickness t₁₂ₐ of the second sub-layer 412a is formed sufficiently thin relative to the thickness t₁₁ₐ of the first sub-layer 411a, the crystallinity of the first nano-composite layer NC1 may be enhanced, resulting in improved hardness.

The crystallinity of the second sub-layer 412a may be determined based on the crystallinity of the first sub-layer 411a, and due to the similarity in crystallinity between the first and second sub-layers 411a and 412a, a first nano-composite layer NC1 with improved crystallinity may be formed between the first and second sub-layers 411a and 412a, resulting in increased hardness. If the thickness t₁₂ₐ of the second sub-layer 412a exceeds 5 nm, the second sub-layer 412a may form an amorphous state due to the distance from the crystal structure of the first sub-layer 411a, potentially reducing the crystallinity and hardness of the first nano-composite layer NC.

The hardness of the first nano-composite layer NC1 is greater than the hardness of the first and second sub-layers 411a and 412a. This is because a structurally more stable first nano-composite layer NC1 is formed at the interface between the first and second sub-layers 411a and 412a.

When the second sub-layer 412a is disposed on the first sub-layer 411a, a thinner second sub-layer 412a reacts with the entire first sub-layer 411a due to nitrogen diffusion, forming the first nano-composite layer NC1 with almost no distinct boundary with the second sub-layer 412a. In this case, since the first nano-composite layer NC1, which has greater hardness than the second sub-layer 412a, is distributed between the first and second sub-layers 411a and 412a, the hardness of the first refractive layer 410 may be further increased.

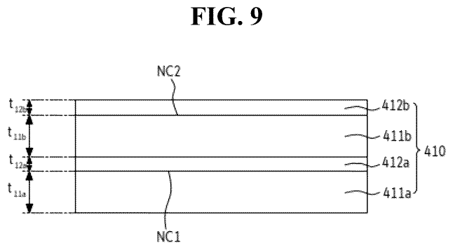

FIG. 9 is a cross-sectional view illustrating an example of the refractive layer of the anti-reflective film in the display device according to an embodiment of the present disclosure.

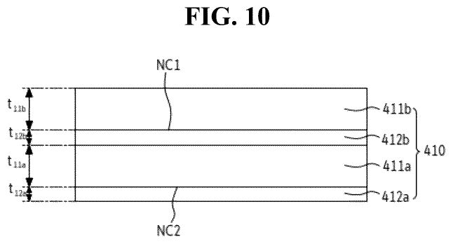

FIG. 10 is a cross-sectional view illustrating an example of the refractive layer of the anti-reflective film in the display device according to an embodiment of the present disclosure.

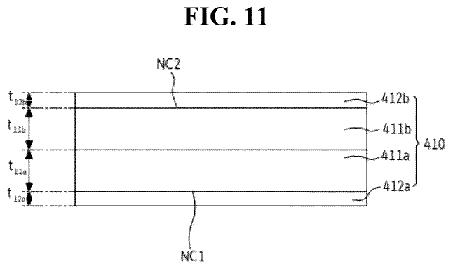

FIG. 11 is a cross-sectional view illustrating an example of the refractive layer of the anti-reflective film in the display device according to an embodiment of the present disclosure.

Referring to FIGS. 9 through 11, the first refractive layer 410 may include a first sub-layer 411a, a second sub-layer 412a, a first nano-composite layer NC1, a third sub-layer 411b, a fourth sub-layer 412b, and a second nano-composite layer NC2.

The examples of FIGS. 9 through 11 differ from the examples of FIGS. 6 and 7 in that the first refractive layer 410 further includes the third sub-layer 411b, the fourth sub-layer 412b, and the second nano-composite layer NC2. The examples of FIGS. 9 through 11 will hereinafter be described, focusing mainly on the differences from the examples of FIGS. 6 and 7, and to the extent that an element is not described in detail with respect to this figure, it may be understood that the element is at least similar to a corresponding element that has been described elsewhere within the present disclosure.

As illustrated in FIG. 9, the first refractive layer 410 may have the second sub-layer 412a disposed on the first sub-layer 411a, the third sub-layer 411b disposed on the second sub-layer 412a, and the fourth sub-layer 412b disposed on the third sub-layer 411b. Alternatively, as illustrated in FIG. 10, the first refractive layer 410 may have the first sub-layer 411a disposed on the second sub-layer 412a, the fourth sub-layer 412b disposed on the first sub-layer 411a, and the third sub-layer 411b disposed on the fourth sub-layer 412b. Further, as illustrated in FIG. 11, the first refractive layer 410 may have the second sub-layer 412a disposed on the first sub-layer 411a, the fourth sub-layer 412b disposed on the first sub-layer 411a, and the third sub-layer 411b disposed on the fourth sub-layer 412b.

The second nano-composite layer NC2 may be formed between the third sub layer 411b and the fourth sub-layer 412b. The second nano-composite layer NC2 may be formed by bonding the material of the third sub layer 411b with the material of the fourth sub-layer 412b. The material of the third sub layer 411b and the material of the fourth sub-layer 412b may have structural similarities.

The stacking order of the first sub-layer 411a, the second sub-layer 412a, the third sub-layer 411b, and the fourth sub-layer 412b may vary depending on the intended purpose of the invention.

The sub-layers 411a, 412a, 411b, and 412b of the first refractive layer 410 may be stacked repeatedly based on characteristics such as hardness, refractive index, and reflectance. FIGS. 9 through 11 illustrate an example where the first refractive layer 410 includes two first group sub-layers 411a and 411b and two second group sub-layers 412a and 412b that are alternately stacked, but the present disclosure is not necessarily limited thereto. For example, the first refractive layer 410 may include only one first group sub-layer and one second group sub-layer, or may include three or more first group sub-layers and three or more second group sub-layers that are alternately stacked.

The first and second nano-composite layers NC1 and NC2 formed between the thicker first group sub-layers 411a and 411b and the thinner second group sub-layers 412a and 412b may have a greater hardness than the first group sub-layers 411a and 411b and the second group sub-layers 412a and 412b. As a result, the hardness of the refractive layer where the first group sub-layers 411a and 411b, the second group sub-layers 412a and 412b, and the first and second nano-composite layers NC1 and NC2 are stacked may be greater than the hardness of a single-layer refractive layer.

Moreover, the anti-reflective film 400 may exhibit greater hardness than an anti-reflective film with a single-layer refractive layer of similar thickness.

Furthermore, the anti-reflective film 400 may have greater hardness even when its thickness is smaller than an anti-reflective film with a single-layer refractive layer.

In summary, the anti-reflective film 400 employing the refractive layer 410 and 430 where the first group sub-layers 411a and 411b, the second group sub-layers 412a and 412b, and the first and second nano-composite layers NC1 and NC2 are stacked can achieve high hardness even with a small thickness, thereby increasing durability. Additionally, when applying the anti-reflective film 400 to a foldable display device, the compressive stress occurring during folding of the foldable display device can be mitigated.

The first, second, third, and fourth sub-layers 411a, 412a, 411b, and 412b may independently include at least one of silicon nitride, metal nitride, and semi-metal nitride.

The first group sub-layers 411a and 411b and the second group sub-layers 412a and 412b may contain different materials. The first and second nano-composite layers NC1 and NC2 may be formed by bonding the material of the first group sub-layers 411a and 411b with the material of the second group sub-layers 412a and 412b.

The metal nitride may include at least one of AlN, ZrN, TiN, CrN, Mn₄N, FeNₓ, CoNₓ, Ni₃N, Cu₃N, Zn₂N₃, VN, Mo₂N, and HfN.

The semi-metal nitride may include Ge₃N₄ or Pb(N₃)₂.

If the first and second sub-layers 411a and 412a include AlN or SiNₓ, respectively, the first nano-composite layer NC1 may include AlSiN, the thickness of the first sub-layer 411a may be at least 10 times the thickness of the second sub-layer 412a, and the thickness of the second sub-layer 412a may be less than 2 nm.

For example, if the first sub-layer 411a includes AlN and the second sub-layer 412a includes SiNx, or if the first and second sub-layers 411a and 412a both include SiNₓ, then the first nano-composite layer NC1 may include AlSiN.

If the first sub-layer 411a includes AlN and the second sub-layer 412a includes ZrN or TiN, the first nano-composite layer NC1 may include AlZrN or AlTiN, the thickness of the first sub-layer 411a may be at least 1.4 times the thickness of the second sub-layer 412a, and the thickness of the second sub-layer 412a may be less than 4 nm.

If the first sub-layer 411a includes CrN and the second sub-layer 412a includes AlN, the first nano-composite layer NC1 may include CrAlN, the thickness of the first sub-layer 411a may be at least 2 times the thickness of the second sub-layer 412a, and the thickness of the second sub-layer 412a may be less than 3 nm.

If the thickness t₁₁ₐ of the first sub-layer 411a is not sufficiently greater than the thickness t₁₂ₐ of the second sub-layer 412a, and/or if the thickness t₁₂ₐ of the second sub-layer 412a exceeds the specified thickness range, the thickness of the first refractive layer 410 may decrease.

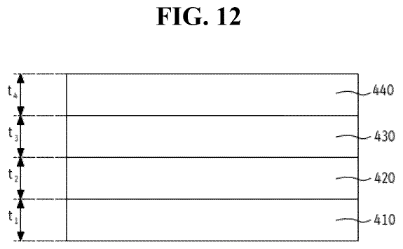

FIG. 12 is a diagram illustrating an example of the anti-reflective film in the display device according to an embodiment of the present disclosure.

The example of FIG. 12 differs from the example of FIG. 5 in that the anti-reflective film 400 further includes a third refractive layer 430 and a fourth refractive layer 440. The example of FIG. 12 will hereinafter be described, focusing mainly on the differences from the example of FIG. 5 and to the extent that an element is not described in detail with respect to this figure, it may be understood that the element is at least similar to a corresponding element that has been described elsewhere within the present disclosure.

Referring to FIG. 12, the third refractive layer 430 may be disposed on the second refractive layer 420, and the fourth refractive layer 440 may be disposed on the third refractive layer 430. The refractive index of the third refractive layer 430 may be greater than the refractive index of the fourth refractive layer 440.

The anti-reflective film 400 may be provided as a multi-layer structure by alternately stacking high-refractive-index and low-refractive-index layers using the characteristics of a distributed Bragg reflector (DBR). The anti-reflective film 400 is illustrated as having the first, second, third, and fourth refractive layers 410, 420, 430, and 440 stacked therein. Alternatively, the anti-reflective film 400 may be provided as a structure with two or up to 100 layers by alternating stacking the high-refractive-index layers 410 and 420 and the low-refractive-index layers 420 and 440.

The third refractive layer 430 may include at least one of Si₃N₄, AlN, zirconium nitride (ZrN), chromium nitride (CrN), titanium nitride (TiN), manganese nitride (Mn₄N), iron nitride (FeNₓ), cobalt nitride (CoNₓ), Ni₃N, Cu₃N, zinc nitride (Zn₂N₃), vanadium nitride (VN), molybdenum nitride (Mo₂N), hafnium nitride (HfN), germanium nitride (Ge₃N₄), lead nitride (Pb(N₃)₂), titanium niobium oxide (Ti₄Nb₃O₃₅), titanium dioxide (TiO₂), zirconium dioxide (ZrO₂), lithium niobate (LiNbO₃), lithium tantalate (LiTaO₃), and lanthanum titanium oxide (LaTiO₂).

However, the third refractive layer 430 is not necessarily limited to these materials, as it may include any material suitable for achieving a high refractive index.

The third refractive layer 430 may be a single layer of a commonly used high-refractive-index material. When the third refractive layer 430 is a single layer, the fabrication process can be simplified compared to the case of fabricating the third refractive layer 430 by alternately stacking the first group sub-layers 411a and 411b and the second group sub-layers 412a and 412b, thereby reducing processing time and cost.

The third refractive layer 430 may be a refractive layer as described in the examples of FIGS. 6, 7, and 9 through 11. Alternatively, the third refractive layer 430 may be a multi-layer structure where the first group sub-layers 411a and 411b and the second group sub-layers 412a and 412b are alternately stacked.

For example, the anti-reflective film 400 may be provided as a multi-layer structure with two or up to 100 layers by alternately stacking the high-refractive-index layers 410 and 430) and the low-refractive-index layers 420 and 440. In this case, some of the high-refractive-index layers 410 and 430 may be multi-layer structures where the first group sub-layers 411a and 411b and the second group sub-layers 412a and 412b are alternately stacked. The other high-refractive-index layers 410 and 430 may be single layers of a high-refractive-index material. For example, if the anti-reflective film 400 is a 10-layer structure where five high-refractive-index layers and five low-refractive-index layers are alternately stacked, two of the five high-refractive-index layers may have first group sub-layers and second group sub-layers alternately stacked, and the other three high-refractive-index layers may be single layers of a high-refractive-index material. This configuration can be adjusted based on the desired hardness, refractive index, and reflectance for the anti-reflective film 400.

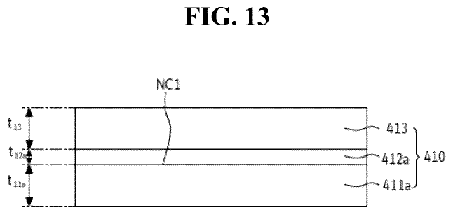

FIG. 13 is a cross-sectional view illustrating a sixth example of the refractive layer of the anti-reflective film in the display device according to an embodiment of the present disclosure.

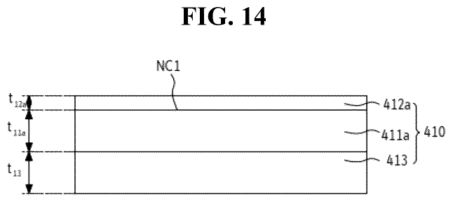

FIG. 14 is a cross-sectional view illustrating a seventh example of the refractive layer of the anti-reflective film in the display device according to an embodiment of the present disclosure.

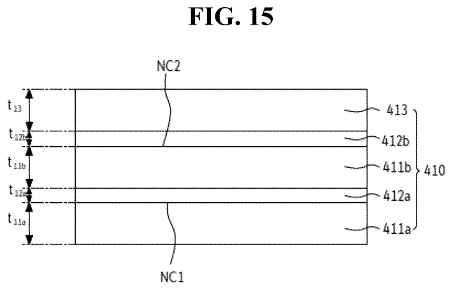

FIG. 15 is a cross-sectional view illustrating an eighth example of the refractive layer of the anti-reflective film in the display device according to an embodiment of the present disclosure.

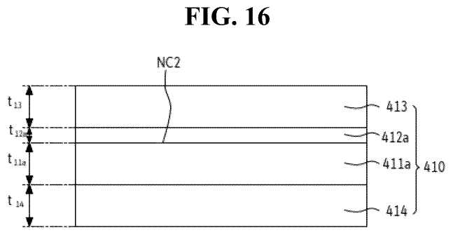

FIG. 16 is a cross-sectional view illustrating a ninth example of the refractive layer of the anti-reflective film in the display device according to an embodiment of the present disclosure.

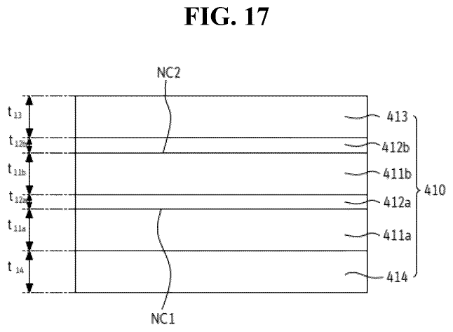

FIG. 17 is a cross-sectional view illustrating a tenth example of the refractive layer of the anti-reflective film in the display device according to an embodiment of the present disclosure.

The examples of FIGS. 13 through 17 differ from the examples of FIGS. 6, 7, and 9 through 11 in that the first refractive layer 410 further includes a third group sub-layer 413 and/or a fourth group sub-layer 414. The examples of FIGS. 13 through 17 will hereinafter be described, focusing mainly on the differences from the examples of FIGS. 6, 7, and 9 through 11, and to the extent that an element is not described in detail with respect to this figure, it may be understood that the element is at least similar to a corresponding element that has been described elsewhere within the present disclosure.

The third group sub-layer 413 may be disposed on one surface of a structure where the first group sub-layers 411a and 411b and the second group sub-layers 412a and 412b are alternately stacked, as in the examples of FIGS. 6, 7, and 9 through 11. Alternatively, the fourth group sub-layer 414 may be disposed on the other surface of the structure where the first group sub-layers 411a and 411b and the second group sub-layers 412a and 412b are alternately stacked.

The third group and fourth group sub-layers 413 and 414 may be formed as single layers of a high-refractive-index material. When the third group and fourth group sub-layers 413 and 414 are single layers, the process of fabricating the third group and fourth group sub-layers 413 and 414 can be simplified compared to the case of fabricating the third group and fourth group sub-layers 413 and 414 by alternately stacking the first group sub-layers 411a and 411b and the second group sub-layers 412a and 412b, thereby reducing processing time and cost.

For example, by alternately stacking the first group sub-layers 411a and 411b and the second group sub-layers 412a and 412b to a required hardness level and disposing the single-layer third group sub-layer 413 and/or the single-layer fourth group sub-layer 414, the time and cost of manufacturing the anti-reflective film 400 can be reduced.

The following examples provide a more detailed description of the invention, though they are intended for illustrative purposes and do not necessarily limit the scope of the invention to one or more particular examples. It is to be understood that all examples are prophetic examples and nothing in this disclosure should be construed as results from actual experiments.

### 1. Fabrication of Refractive Layers

### 1) Embodiment 1

Refractive layers with a total thickness of 160 nm were fabricated on a glass substrate by alternately stacking 50 nm of AlN as first group sub-layers and 1 nm of Si₃N₄ as second group sub-layers.

### 2) Comparative Example 1

A glass substrate was used as Comparative Example 2.

### 3) Comparative Example 2

Refractive layers with a thickness of 160 nm were fabricated by depositing AlN on a glass substrate.

### 4) Comparative Example 3

Refractive layers similar to those in Embodiment 1 were fabricated, except that 8 nm of Si₃N₄ was used as the second group sub-layer.

### 2. Fabrication of Anti-Reflective Films

Anti-reflective films according to Embodiments 2 through 4 and Comparative Examples 4 through 8 were fabricated as shown in Table 1 below.

The low-refractive-index layers (i.e., first, third, fifth, seventh, ninth, eleventh, and thirteenth refractive layers) in Embodiments 2 through 4 were formed by stacking SiO₂ to the thicknesses specified in Table 1. The high-refractive-index layers (second, fourth, sixth, eighth, tenth, and twelfth refractive layers) in Embodiments 2 through 4 were formed by alternately stacking 20 nm of AlN as the first group sub-layer and 1 nm of Si₃N₄ as the second group sub-layer to the thicknesses specified in Table 1.

Low-refractive-index layers (i.e., first, third, fifth, seventh, ninth, eleventh, and thirteenth refractive layers) in Comparative Examples 4 through 8 were stacked to the thicknesses specified in Table 1, using SiO₂. High-refractive-index layers (i.e., second, fourth, sixth, eighth, tenth, and twelfth refractive layers) in Comparative Examples 4 trough 8 were stacked to the thicknesses specified in Table 1, using Si₃N₄.

TABLE 1

| Thickness | | | | Comparative | Comparative | Comparative | Comparative | Comparative |
|---|---|---|---|---|---|---|---|---|
| (nm) | Embodiment 2 | Embodiment 3 | Embodiment 4 | Example 4 | Example 5 | Example 6 | Example 7 | Example 8 |
| 1^{st} | 87.8 | 85.8 | 80.1 | 86.6 | 85.1 | 89.8 | 83.8 | 84.8 |
| Refractive | | | | | | | | |
| Layer | | | | | | | | |
| 2^{nd} | 175.3 | 174 | 146.6 | 159.3 | 176.8 | 148.1 | 154.8 | 159.5 |
| Refractive | | | | | | | | |
| Layer | | | | | | | | |
| 3^{rd} | 20 | 13.5 | 13.9 | 37 | 11.8 | 14.6 | 10 | 14.5 |
| Refractive | | | | | | | | |
| Layer | | | | | | | | |
| 4^{th} | 57.1 | 64 | 171.3 | 23.1 | 60 | 177.5 | 192.8 | 186.7 |
| Refractive | | | | | | | | |
| Layer | | | | | | | | |
| 5^{th} | 45.5 | 22 | 10 | 19.5 | 42.5 | 8 | 5 | 10.1 |
| Refractive | | | | | | | | |
| Layer | | | | | | | | |
| 6^{th} | 20 | 30 | 184.2 | | 19.7 | 272.9 | 197.5 | 182.6 |
| Refractive | | | | | | | | |
| Layer | | | | | | | | |
| 7^{th} | 20 | 39 | 10.1 | | 52.1 | 23.4 | 5 | 10 |
| Refractive | | | | | | | | |
| Layer | | | | | | | | |
| 8^{th} | | 24.3 | 51.1 | | | 30.8 | 172.2 | 174.6 |
| Refractive | | | | | | | | |
| Layer | | | | | | | | |
| 9^{th} | | 68 | 35.1 | | | 52.7 | 9.6 | 13.9 |
| Refractive | | | | | | | | |
| Layer | | | | | | | | |
| 10^{th} | | 13 | 23.1 | | | 10.6 | 164.3 | 156.9 |
| Refractive | | | | | | | | |
| Layer | | | | | | | | |
| 11^{th} | | 65 | 29.5 | | | 66.1 | 35.7 | 34.8 |
| Refractive | | | | | | | | |
| Layer | | | | | | | | |
| 12^{th} | | | | | | | 17.5 | 16.6 |
| Refractive | | | | | | | | |
| Layer | | | | | | | | |
| 13^{th} | | | | | | | 43.6 | 35.6 |
| Refractive | | | | | | | | |
| Layer | | | | | | | | |
| Total | 426 | 599 | 755 | 325.6 | 447.9 | 894.5 | 1091.7 | 1081 |
| Thickness | | | | | | | | |
| High | 59% | 51% | 76% | 56.00% | 57.30% | 71.50% | 82.40% | 81% |
| R.I. % | | | | | | | | |
| Reflectance | 0.65% | 0.61% | 0.7% | 0.58% | 0.40% | 0.84% | 0.52% | 0.59% |

In Table 1, “high R.I.%” indicates the proportion of high-refractive-index layers in the anti-reflective films. According to the results shown in Table 1, it can be observed that all the anti-reflective films according to Embodiments 2 through 4 and Comparative Examples 4 through 8 achieve a low reflectance of less than 1%.

### Evaluation

### 1. Hardness Measurement by Sub-Layer Thickness

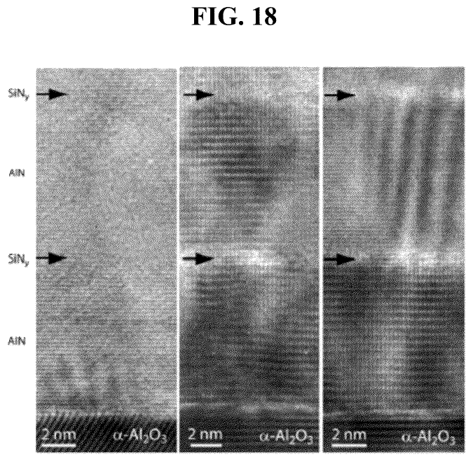

FIG. 18 presents High Resolution-Transmission Electron Microscopy (HR-TEM) images illustrating the effect of the thickness of the second group sub-layers in the refractive layers according to embodiments.

For example, FIG. 18 shows HR-TEM images of the refractive layers when AlN in the first group sub-layers has a thickness of 20 nm and Si₃N₄ in the second group sub-layers, stacked on the first group sub-layers, have thicknesses of 0.7 nm, 1.5 nm, and 2.0 nm.

According to the results shown in FIG. 18, it can be observed that as the thickness of Si₃N₄ in the second group sub-layers decreases, the second group sub-layers can fully bond with the first group sub-layers to form nano-composites, thereby eliminating the boundaries.

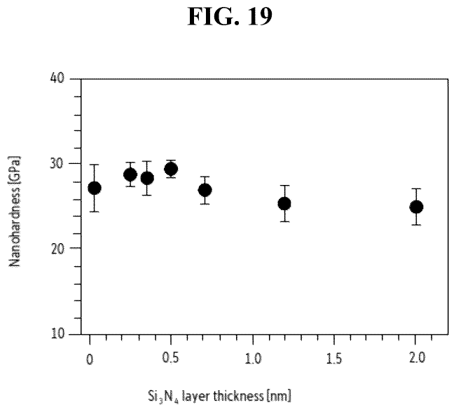

FIG. 19 is a graph showing the hardness of the refractive layer as a function of the thickness of the second group sub-layers in the refractive layers according to embodiments of the present disclosure.

For example, FIG. 19 is a graph showing the hardness corresponding to the thickness of Si₃N₄ as the second group sub-layers when the AlN in the group first sub-layers has a thickness of 20 nm.

According to the results shown in FIG. 19, it can be seen that as the thickness of the second group sub-layers decreases, the hardness of the refractive layers increases.

Table 2 below shows the hardnesses of the refractive layers according to Embodiment 1 and Comparative Examples 1 through 3 for various indentation depths.

TABLE 2

| | Hardness (GPa) | | | |
|---|---|---|---|---|
| Indentation | | Comparative | Comparative | Comparative |
| Depth (nm) | Embodiment 1 | Example 1 | Example 2 | Example 3 |
| 50 | 14.8 | 7.9 | 10.9 | 12.8 |
| 100 | 11.4 | 8.2 | 10.5 | 10.6 |
| 150 | 10.7 | 8.6 | 10.3 | 10 |
| 200 | 10.4 | 8.9 | 10.1 | 9.9 |

According to the results shown in Table 2, it can be observed that the hardness of Embodiment 1 is highest at various indentation depths. In particular, Embodiment 1 exhibits greater hardness at each indentation depth than Comparative Example 2, which provides single-layer structures of the same thickness, and Comparative Example 3, which provides thicker second group sub-layers.

According to the results shown in FIGS. 18 and 19 and Table 2, it can be confirmed that as the thickness of the second group sub-layers decreases, the second group sub-layers fully bond with the first group sub-layers to form nano-composites with higher hardness than the first group sub-layers and the second group sub-layers. If the thickness of the second group sub-layers is not sufficiently thin, the hardness of the refractive layers may decrease due to the relatively lower hardness of the second group sub-layers compared to the nano-composites. In other words, when the thickness of the second group sub-layers is sufficiently thin relative to the first group sub-layers, fully formed nano-composites with enhanced hardness can be obtained.

### 2. Hardness Measurement by Anti-Reflective Film Thickness

Table 3 below shows the hardnesses of the anti-reflective films according to Embodiments 2 through 4 and Comparative Examples 4 through 8 for various indentation depths.

TABLE 3

| | Hardness (GPa) | | | | | | | |
|---|---|---|---|---|---|---|---|---|
| Indentation | | | | Comparative | Comparative | Comparative | Comparative | Comparative |
| Depth | Embodiment 2 | Embodiment 3 | Embodiment 4 | Example 4 | Example 5 | Example 6 | Example 7 | Example 8 |
| 100 | 18.2 | 18.4 | 18.8 | 10.7 | 11.8 | 11.3 | 11.1 | 15 |
| 200 | 19.6 | 20.5 | 23.3 | 11.4 | 14.5 | 14.0 | 14.8 | 18.2 |
| 200 | 16.5 | 17.2 | 22.9 | 14.7 | 17.4 | 19.2 | 21.3 | 19.9 |

According to the results shown in Table 3, when comparing Embodiment 2 with a total thickness of 426 nm to Comparative Example 5 with a total thickness of 447.9 nm, it can be observed that Embodiment 2, which uses multi-layer high-refractive-index layers, has a higher hardness (18.2 GPa, 19.6 GPa, 16.5 GPa) than Comparative Example 5, which uses a single-layer refractive layer (11.8 GPa, 14.5 GPa, 17.4 GPa). Additionally, when comparing Embodiments 3 and 4, with total thicknesses of 599 nm and 755 nm, respectively, to Comparative Example 6 with a total thickness of 894.5 nm, it can be observed that the hardness of Embodiment 3 (18.4 GPa, 20.5 GPa, 17.2 GPa) and Embodiment 4 (18.8 GPa, 23.3 GPa, 22.9 GPa) is higher than that of Comparative Example 6 (11.3 GPa, 14.0 GPa, 19.2 GPa), which uses a single-layer refractive layer. This demonstrates that hardness is increased by using a high-refractive-index layer formed by alternately stacking thin and thick high-refractive-index layers, when comparing anti-reflective films of similar total thickness.

Furthermore, it can be observed that Embodiments 3 and 4, which have a relatively small total thickness, show greater hardness than Comparative Examples 7 and 8, which have a greater total thickness. This indicates that when a high-refractive-index layer obtained by alternately stacking thin and thick high-refractive-index layers is applied, the hardness is increased, allowing for sufficient hardness even with a relatively small total thickness. Particularly, even for a thinner anti-reflective film, high hardness can still be achieved, thereby reducing processing cost and minimizing compressive stress when applied to a foldable display.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary and not necessarily restrictive.

What is claimed is:

1. An anti-reflective film, comprising:
a first refractive layer; and
a second refractive layer disposed on the first refractive layer,
wherein a refractive index of the first refractive layer is greater than a refractive index of the second refractive layer,
wherein the first refractive layer comprises:
a first sub-layer; and
a second sub-layer disposed on the first sub-layer,
wherein a first nano-composite layer is formed between the first sub-layer and the second sub-layer,
wherein the first nano-composite layer comprises a material formed by bonding a material of the first sub-layer with a material of the second sub-layer,
wherein a thickness of the first sub-layer is at least 1.2 times larger than a thickness of the second sub-layer, and
wherein the thickness of the second sub-layer is less than 5 nm.

2. The anti-reflective film of claim 1,
wherein the first refractive layer further comprises:
a third sub-layer disposed on the second sub-layer; and
a fourth sub-layer disposed on the third sub-layer,
wherein a second nano-composite layer is formed between the third sub-layer and the fourth sub-layer,
wherein the second nano-composite layer comprises a material formed by bonding a material of the third sub-layer with a material of the fourth sub-layer,
wherein a thickness of the third sub-layer is at least 1.2 times larger than a thickness of the fourth sub-layer, and
wherein the thickness of the fourth sub-layer is less than 5 nm.

3. The anti-reflective film of claim 2, wherein the first sub-layer, the second sub-layer, the third sub-layer, and the fourth sub-layer each independently comprise at least one of silicon nitride, a metal nitride, and a semi-metal nitride.

4. The anti-reflective film of claim 3, wherein the metal nitride comprises at least one of AlN, ZrN, TiN, CrN, Mn₄N, FeNₓ, CoNₓ, Ni₃N, Cu₃N, Zn₂N₃, VN, Mo₂N, and HfN.

5. The anti-reflective film of claim 3, wherein the semi-metal nitride comprises Ge₃N₄ or Pb(N₃)₂.

6. The anti-reflective film of claim 3,
wherein the first sub-layer and the second sub-layer respectively comprises AlN or SiNₓ,
wherein the first nano-composite layer comprises AlSiN,
wherein a thickness of the first sub-layer is at least 10 times larger a thickness of the second sub-layer, and
wherein the thickness of the second sub-layer is less than 2 nm.

7. The anti-reflective film of claim 3,
wherein when the first sub-layer comprises AlN and the second sub-layer comprises ZrN or TiN, the first nano-composite layer comprises AlZrN or AlTiN,
wherein a thickness of the first sub-layer is at least 1.4 times larger than a thickness of the second sub-layer, and
wherein the thickness of the second sub-layer is less than 4 nm.

8. The anti-reflective film of claim 3,
wherein in case that the first sub-layer comprises CrN and the second sub-layer comprises AlN, the first nano-composite layer comprises CrAlN, a thickness of the first sub-layer is at least 2 times larger than a thickness of the second sub-layer, and the thickness of the second sub-layer is less than 3 nm.

9. The anti-reflective film of claim 1, further comprising:
a third refractive layer disposed on the second refractive layer; and
a fourth refractive layer disposed on the third refractive layer,
wherein a refractive index of the third refractive layer is greater than a refractive index of the fourth refractive layer.

10. The anti-reflective film of claim 9,
wherein the third refractive layer comprises:
a fifth sub-layer; and
a sixth sub-layer disposed on the fifth sub-layer,
wherein a third nano-composite layer is formed between the fifth sub-layer and the sixth sub-layer,
wherein the third nano-composite layer comprises a material formed by bonding the material of the fifth sub-layer with the material of the sixth sub-layer,
wherein a thickness of the fifth sub-layer is at least 1.2 times larger than a thickness of the sixth sub-layer, and
wherein the thickness of the sixth sub-layer is less than 5 nm.

11. The anti-reflective film of claim 1, wherein the anti-reflective film has a hardness of at least 20 GPa at a thickness of 50 nm to 600 nm.

12. The anti-reflective film of claim 1, wherein the anti-reflective film has a hardness of at least 22 GPa at a thickness of 600 nm to 800 nm.

13. The anti-reflective film of claim 1, wherein the anti-reflective film has a hardness of at least 24 GPa at a thickness of 800 nm to 1,000 nm.

14. The anti-reflective film of claim 1, further comprising:
a third group sub-layer disposed on the second sub-layer.

15. The anti-reflective film of claim 14, wherein the third group sub-layer comprises at least one selected from the group consisting of silicon nitride (Si₃N₄), aluminum nitride (AlN), zirconium nitride (ZrN), chromium nitride (CrN), titanium nitride (TiN), manganese nitride (Mn₄N), iron nitride (FeNₓ), cobalt nitride (CoNₓ), nickel nitride (Ni₃N), copper nitride (Cu₃N), zinc nitride (Zn₂N₃), vanadium nitride (VN), molybdenum nitride (Mo₂N), hafnium nitride (HfN), germanium nitride (Ge₃N₄), lead nitride (Pb(N₃)₂), titanium niobium oxide (Ti₄Nb₃O₃₅), titanium dioxide (TiO₂), zirconium dioxide (ZrO₂), lithium niobate (LiNbO₃), lithium tantalate (LiTaO₃), and lanthanum titanium oxide (LaTiO₂).

16. The anti-reflective film of claim 14, wherein the first refractive layer further comprises a fourth sixth sub-layer disposed on the other surface of the 1a-thfirst sub-layer.

17. A display device, comprising:
a display panel;
an anti-reflective film disposed on the display panel; and
a window disposed on the anti-reflective film,
wherein the anti-reflective film comprises:
a first refractive layer; and
a second refractive layer disposed on the first refractive layer,
wherein a refractive index of the first refractive layer is greater than a refractive index of the second refractive layer,
wherein the first refractive layer comprises:
a first sub-layer; and
a second sub-layer disposed on one surface of the first sub-layer,
wherein a first nano-composite layer is formed between the first sub-layer and the second sub-layer,
wherein the first nano-composite layer comprises a material formed by bonding a material of the first sub-layer with a material of the second sub-layer,
wherein a thickness of the first sub-layer is at least 1.2 times larger than a thickness of the second sub-layer, and
wherein the thickness of the second sub-layer is less than 5 nm.

18. The display device of claim 17, wherein the first refractive layer further comprises a third sub-layer disposed on the second sub-layer.

19. The display device of claim 17, wherein the first refractive layer further comprises a fourth sub-layer disposed on another surface of the first sub-layer.

20. An electronic device, comprising:
a display device configured to display an image; and
a processor configured to transmit an image data signal to the display device,
wherein the display device, comprises:
a display panel;
an anti-reflective film disposed on the display panel; and
a window disposed on the anti-reflective film,
wherein the anti-reflective film comprises:
a first refractive layer; and
a second refractive layer disposed on the first refractive layer,
wherein a refractive index of the first refractive layer is greater than a refractive index of the second refractive layer,
wherein the first refractive layer comprises:
a first sub-layer; and
a second sub-layer disposed on one surface of the first sub-layer,
wherein a first nano-composite layer is formed between the first sub-layer and the second sub-layer,
wherein the first nano-composite layer comprises a material formed by bonding a material of the first sub-layer with a material of the second sub-layer,
wherein a thickness of the first sub-layer is at least 1.2 times larger than a thickness of the second sub-layer, and
wherein the thickness of the second sub-layer is less than 5 nm.
